(19) United States
(12) Patent Application Publication
(10) Pub. No.: US 2025/0194007 A1
(43) Pub. Date: Jun. 12, 2025

(54) ELECTRONIC DEVICE

(71) Applicant: InnoLux Corporation, Miao-Li County (TW)

(72) Inventors: Chia-Chun LIU, Miao-Li County (TW); Hao-Jung HUANG, Miao-Li County (TW); Ker-Yih KAO, Miao-Li County (TW)

(21) Appl. No.: 18/941,367

(22) Filed: Nov. 8, 2024

Related U.S. Application Data
(60) Provisional application No. 63/607,148, filed on Dec. 7, 2023.

(30) Foreign Application Priority Data
Jun. 27, 2024 (CN) 202410847019.3

(51) Int. Cl. H05K 1/11; H01L 23/498; H01L 23/538; H05K 1/18

(52) U.S. Cl. CPC H05K 1/112; H01L 23/49816; H01L 23/5385; H05K 1/181

(57) ABSTRACT

An electronic device is provided. The electronic device includes at least one electrical connection structure. The at least one electrical connection structure includes a first substrate, a first conductive pad, a second substrate, a second conductive pad, a first conductive material, a through-hole, and a second conductive material. The first conductive pad is disposed on the first substrate and has a top surface and a side surface. The second conductive pad is disposed on the second substrate. The first conductive material is disposed on the second conductive pad. The through-hole passes through the first conductive pad and the first substrate. The second conductive material is partially disposed within the through-hole and is at least partially in contact with the top surface and the side surface of the first conductive pad, and the first conductive material.

### CROSS REFERENCE TO RELATED APPLICATIONS

This application claims the benefit of China Application No. 202410847019.3, filed Jun. 27, 2024, which claims the benefit of provisional Application No. 63/607,148, filed Dec. 7, 2023, the entirety of which are incorporated by reference herein.

### BACKGROUND

### Technical Field

The present disclosure is related to an electronic device, and in particular it is related to an electrical connection structure of an electronic device.

### Description of the Related Art

Electronic devices such as tablet computers, notebook computers, smartphones, monitors, and televisions have become indispensable necessities in modern society. With the application of electronic devices and the habits or needs of users, the requirements for the structure and quality of electronic devices are getting higher and higher, which in turn causes the manufacturers of electronic devices to face different problems.

For example, in response to higher resolution or display quality requirements, the size of the electrical connection structure in an electronic device needs to be miniaturized accordingly, thereby affecting the reliability or conduction capability of the electrical connection structure.

Based on the above, existing electronic devices still do not meet requirements in all respects. Further improving the performance of the electrical connection structure of electronic devices is still one of the current research topics in the industry.

### SUMMARY

In accordance with some embodiments of the present disclosure, an electronic device is provided. The electronic device includes at least one electrical connection structure. Said electrical connection structure includes a first substrate, a first conductive pad, a second substrate, a second conductive pad, a first conductive material, a through-hole, and a second conductive material. The first conductive pad is disposed on the first substrate and has a top surface and a side surface. The second conductive pad is disposed on the second substrate. The first conductive material is disposed on the second conductive pad. The through-hole passes through the first conductive pad and the first substrate. The second conductive material is partially disposed within the through-hole and is at least partially in contact with the top surface and the side surface of the first conductive pad, and the first conductive material.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a top-view diagram of an electronic device in accordance with some embodiments of the present disclosure;

FIG. 2 is a cross-sectional diagram of an electronic device taken along the section line A-A′ in FIG. 1 in accordance with some embodiments of the present disclosure;

FIG. 3 is a top-view diagram of some elements of an electrical connection structure of an electronic device in accordance with some embodiments of the present disclosure;

FIGS. 4A to 4F are cross-sectional diagrams of an electrical connection structure of an electronic device in accordance with some embodiments of the present disclosure;

FIGS. 5A to 5F are cross-sectional diagrams of an electrical connection structure of an electronic device in accordance with some embodiments of the present disclosure;

FIGS. 6A to 6F are cross-sectional diagrams of an electrical connection structure of an electronic device in accordance with some embodiments of the present disclosure;

FIG. 7 is a cross-sectional diagram of an electronic device in accordance with some embodiments of the present disclosure.

### DETAILED DESCRIPTION

The electronic device according to the present disclosure is described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to ensure that an element with a certain name can be clearly distinguishable from another element with the same name. Claims and the specification may not use the same terms. For example, the first element in the specification may refer to the second element in the claims. In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “coupled to” may include any direct or indirect electrical connection means.

In the following descriptions, terms “about”, “substantially” and “approximately” typically mean+/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. Moreover, certain errors may exist between any two values or directions used for comparison. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

Moreover, in accordance with the embodiments of the present disclosure, a scanning electron microscope (SEM), an optical microscope (OM), a film thickness profiler (α-step), an ellipsometer or another suitable method may be used to measure the width, length, thickness, height, volume or area of each element, or distance or spacing between elements. Specifically, in accordance with some embodiments, a scanning electron microscope can be used to obtain cross-sectional images of the structure and measure the width, length, thickness, height, volume or area of each element, or distance or spacing between elements.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In response to higher demands for resolution or display quality, the dimensions of electrical connection structures in electronic devices need to be correspondingly miniaturized. As a result, the reliability and conduction performance of these electrical connection structures face significant challenges.

In accordance with the embodiments of the present disclosure, an electronic device is provided that includes an electrical connection structure. The electrical connection structure includes specifically configured conductive pads and conductive materials, which can reduce the volume of the through-holes, decrease the required amount of conductive material, or reduce the depth of the through-holes. This allows for a larger tolerance margin in the conductive material filling and/or through-hole processing, thereby improving process yield. By the aforementioned configuration of the conductive pads and conductive materials, the electrical connection structure can achieve enhanced reliability, which supports the miniaturization of the electrical connection structure. In addition, in accordance with the embodiments of the present disclosure, the design of the electrical connection structure allows electronic components (e.g., driving elements) to be placed on the backside of the substrate, reducing the peripheral usage of the electronic device and thereby meeting technological requirements such as bezel-free, narrow-bezel, or seamless tiling designs.

In accordance with some embodiments of the present disclosure, the electronic device may include a display device, a tiled device, a touch electronic device, a sensing device, an antenna device, a packaging device, a curved electronic device or a non-rectangular electronic device, but it is not limited thereto. The electronic device may include, for example, liquid crystal, light-emitting diode, fluorescence, phosphor, other suitable display media, or a combination thereof, but it is not limited thereto. The display device may be a non-self-luminous display device or a self-luminous display device. The electronic device may include electronic components, which may be passive components or active components, such as capacitors, resistors, inductors, diodes, driving components, transistors, etc. The diode may include a light-emitting diode (LED) or a photodiode. The light-emitting diode may include, for example, an organic light-emitting diode (OLED), a mini light-emitting diode (mini LED), a micro light-emitting diode (micro LED) or a quantum dot light-emitting diode (quantum dot LED), but it is not limited thereto. The tiled device may be, for example, a tiled display device, but it is not limited thereto. The antenna device may be, for example, a liquid-crystal antenna or a varactor diode antenna device, but it is not limited thereto. The packaging device may be used in wafer level packaging (WLP) technology or panel level packaging (PLP) technology, such as chip first or RDL first process. It should be noted that the electronic device can be any combination of the above, but it is not limited thereto. In addition, the electronic device may be a bendable or flexible electronic device. Moreover, the shape of the electronic device may be a rectangular shape, a circular shape, a polygonal shape, a shape with curved edges, or other suitable shapes. The electronic device may have a peripheral system such as a driving system, a control system, a light source system, a shelf system, etc. to support a display device or tiled device.

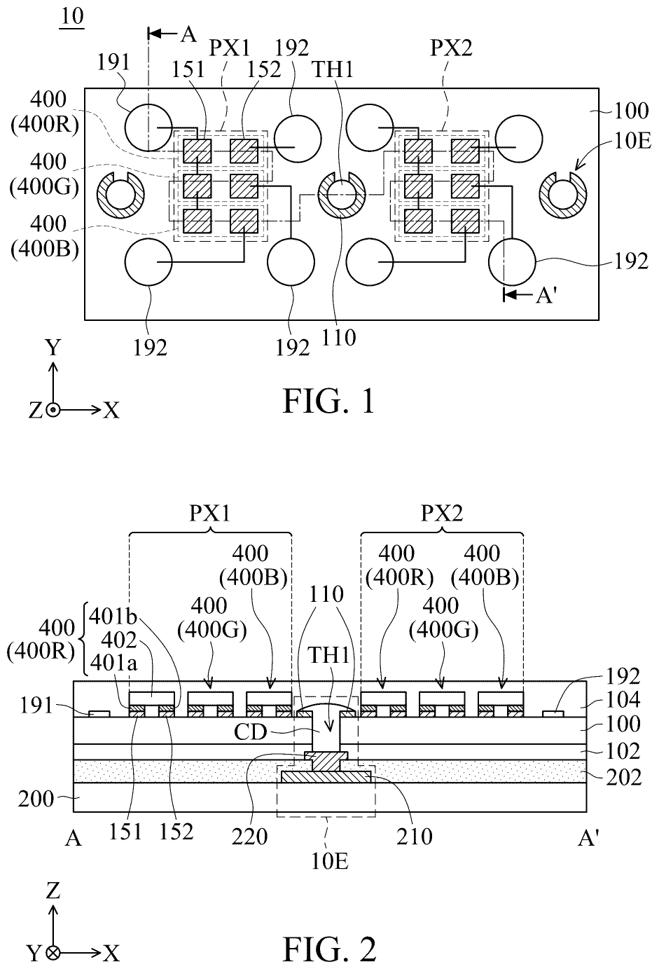

Please refer to FIG. 1 and FIG. 2. FIG. 1 is a top-view diagram of an electronic device 10 in accordance with some embodiments of the present disclosure. FIG. 2 is a cross-sectional diagram of the electronic device 10 taken along the section line A-A′ in FIG. 1 in accordance with some embodiments of the present disclosure. It should be understood that, for clarity of explanation, some components of the electronic device 10 may be omitted in the drawings, and only some components are schematically illustrated. In accordance with some embodiments, additional features may be added to the electronic device 10 described below. In accordance with some other embodiments, some features of the electronic device 10 described below may be replaced or omitted.

The electronic device 10 includes at least one electrical connection structure 10E. In the following description, the electronic device 10 is used as a display device and the electrical connection structure 10E is applied to the display device as an example, but the present disclosure is not limited thereto. It should be understood that the electrical connection structure 10E can also be applied to another suitable electronic device to provide electrical connection functions.

As shown in FIG. 1 and FIG. 2, in accordance with some embodiments, the electronic device 10 includes a first substrate 100, a second substrate 200, an electronic component 400, and an electrical connection structure 10E. The second substrate 200 may be disposed opposite to the first substrate 100. The electronic component 400 may be disposed on the first substrate 100, and the electronic component 400 may be electrically connected to another electronic component (not illustrated, such as a driving component, etc.) on the second substrate 200 through the electrical connection structure 10E. In accordance with some embodiments, the electronic component 400 includes a light-emitting diode, and the electronic device 10 can be, for example, a light-emitting diode display device. In this way, the electronic component 400 can be driven by another electronic component (not illustrated, which can be a driving component, etc.) disposed on the back side of the first substrate 100, which can reduce the usage rate of the usage rate of the peripheral area of the electronic device 10, thereby achieving technical requirements such as bezel-free, narrow-bezel, or seamless tiling with good display quality.

In accordance with some embodiments, the first substrate 100 can be used as an active array substrate, and includes, for example, a base (not illustrated) and a circuit element layer (not illustrated) disposed on the base. The base of the first substrate 100 may include a rigid substrate, a flexible substrate, or a combination thereof. In accordance with some embodiments, the material of the base of the first substrate 100 may include glass, quartz, sapphire, polyimide (PI), polycarbonate (PC), polyethylene terephthalate (PET), polypropylene (PP), polydimethylsiloxane (PDMS), another suitable base material or a combination thereof, but it is not limited thereto. Furthermore, the circuit element layer may include, for example, a stack of at least one or more circuit elements (e.g., thin-film transistors), buffer layers, and insulating layers, but it is not limited thereto. In accordance with some embodiments, the circuit element layer is, for example, an active array layer composed of a plurality of thin-film transistors, but it is not limited thereto.

Please continue to refer to FIG. 1 and FIG. 2. In accordance with some embodiments, one or more electronic components 400 may form a pixel, and multiple pixels (for example, a pixel PX1 and a pixel PX2) may be disposed on the first substrate 100. As described above, the electronic component 400 may be a light-emitting diode. In other words, in accordance with some embodiments, each pixel may include multiple light-emitting diodes (for convenience of explanation, they are labeled as an electronic component 400R, an electronic component 400G and an electronic component 400B in FIG. 1), and the number of light-emitting diodes is not limited. For example, the two pixels PX1 and PX2 shown in FIG. 1 may be arranged in an array by the X-axis and Y-axis directions in the figure (the X-axis is perpendicular to the Y-axis and Z-axis, and the Y-axis is perpendicular to the X-axis and Z-axis), but it is not limited thereto. It should be understood that the number pixels and the arrangement pattern shown in FIG. 1 are only examples. In fact, the number of pixels may be tens, tens of thousands, or millions or more, but it is not limited thereto.

In accordance with some embodiments, the plurality of light-emitting diodes may include red light-emitting diodes, green light-emitting diodes, blue light-emitting diodes, white light-emitting diodes, yellow light-emitting diodes or light-emitting diodes of other colors, which can be adjusted according to design requirements. In accordance with some embodiments, the aforementioned electronic component 400R, electronic component 400G and electronic component 400B can serve as sub-pixels, and a combination of multiple pixels PX1 and pixels PX2 can be used to generate image patterns. In accordance with some embodiments, the amount of the light-emitting diodes in the pixel PX1 and the pixel PX2 may be three or more, and the colors of the light-emitting diodes may include red light, blue light, green light, white light, yellow light, light or another suitable color, but it is not limited thereto.

In accordance with some embodiments, the electronic component 400 may include an electrode 401a, an electrode 401b, and a body portion 402. The body portion 402 may include, for example, a first-type semiconductor layer (such as an N-type doped semiconductor layer), a second-type semiconductor layer (such as a P-type doped semiconductor layer), and a light-emitting layer located between the first-type semiconductor layer and the second-type semiconductor layer. That is, the body portion 402 may be a p-n junction light-emitting diode, but it is not limited thereto. Furthermore, although the electronic component 400 illustrated in the figure is a flip-chip LED, the present disclosure is not limited thereto. In accordance with some other embodiments, the electronic component 400 may also include a vertical LED, a face-up LED, or LED packaged by another suitable manner.

In accordance with some embodiments, the electronic component 400 may be electrically connected to the circuit element layer of the first substrate 100. Specifically, a plurality of first pads 151 and a plurality of second pads 152 may be disposed on the first substrate 100 or the circuit element layer. One of the plurality of light-emitting diodes may be disposed corresponding to the first contact pad 151 and the adjacent second contact pad 152. For example, the electrode 401a of the electronic component 400R may be electrically connected to the first contact pad 151, and the electrode 401b may be electrically connected to the second contact pad 152, but it is not limited thereto. In this way, the first contact pad 151 and the second contact pad 152 can respectively serve as pads connected to the positive electrode or the negative electrode of the electronic component 400. For example, the electronic component 400 may be electrically connected to the first contact pad 151 and the second contact pad 152 through wire bonding, flip-chip die bonding, or eutectic die bonding etc. In addition, in accordance with some other embodiments, the electronic component 400 may also use a transfer layer including conductive lines and insulating layers, so that the electrode 401a and/or the electrode 402b can be electrically connected to the circuit elements (for example, thin-film transistors) or circuit layers in the circuit element layer through the conductive lines, but it is not limited thereto.

In accordance with some embodiments, the electronic device 10 may optionally include a first test pad 191 and a plurality of second test pads 192. The first test pad 191 and the second test pads 192 may be respectively disposed adjacent to one side of the pixel (for example, the pixel PX1), but it is not limited thereto. The first test pad 191 and the second test pads 192 may be electrically connected to the circuit element layer of the first substrate 100, but it is not limited thereto. The first test pad 191 may connect multiple first pads 151 in series. The second test pads 192 may be electrically connected to the second pads 152 respectively. In accordance with some embodiments, the first test pad 191 and the second test pads 192 can serve as test electrodes for detecting the electrical quality of the plurality of electronic components 400 in the pixel PX1 and the pixel PX2.

The materials of the first test pad 191, the second test pad 192, the first contact pad 151 and the second contact pad 152 may include conductive materials. In accordance with some embodiments, the first test pad 191, the second test pad 192, the first contact pad 151 and the second contact pad 152 may include a metal conductive material, such as molybdenum (Mo), titanium (Ti), Tantalum (Ta), niobium (Nb), hafnium (Hf), nickel (Ni), chromium (Cr), cobalt (Co), zirconium (Zr), tungsten (W), aluminum (Al), copper (Cu), tin (Sn), silver (Ag), gold (Au), alloys of the above materials, another suitable conductive material or a combination thereof, but it is not limited thereto. In accordance with some embodiments, the first test pad 191, the second test pad 192, the first contact pad 151 and the second contact pad 152 may include a transparent conductive material. The transparent conductive material may include, for example, a transparent conductive oxide (TCO), such as indium tin oxide (ITO), antimony zinc oxide (AZO), tin oxide (SnO), zinc oxide (ZnO), indium zinc oxide (indium zinc oxide, IZO), indium gallium zinc oxide (IGZO), indium tin zinc oxide (ITZO), antimony tin oxide (ATO), another suitable transparent conductive material, or a combination thereof, but it is not limited thereto.

As shown in FIG. 2, in accordance with some embodiments, the electronic device 10 may further include a cover layer 104 disposed on the first substrate 100. Furthermore, in accordance with some embodiments, the cover layer 104 may be disposed on the circuit element layer of the first substrate 100, the cover layer 104 may cover the first test pad 191 and the second test pad 192, and may at least partially cover electronic component 400. In accordance with some embodiments, the cover layer 104 may cover the plurality of electronic components 400 and the electrical connection structure 10E. In accordance with some embodiments, the cover layer 104 may cover the first test pad 191, the second test pad 192, the plurality of electronic components 400 and the electrical connection structure 10E, but it is not limited thereto. The cover layer 104 can provide at least one of the functions of electrical insulation, protection of the related components that are covered, flat surface, etc. The cover layer 104 may be formed by coating, jetting, dispensing, printing or another suitable method, but it is not limited thereto. In accordance with some embodiments, the cover layer 104 may include an inorganic material, an organic material, or a combination thereof, but it is not limited thereto. In accordance with some embodiments, the inorganic material may include silicon nitride, silicon oxide, silicon oxynitride, aluminum oxide, another suitable material, or a combination thereof, but it is not limited thereto. In accordance with some embodiments, the organic material may include, for example, perfluoroalkoxy alkane (PFA), polytetrafluoroethylene (PTFE), perfluorinated ethylene propylene (FEP), polyethylene, silicone, acrylic, polyurethane epoxy, another suitable material or a combination thereof, but it is not limited thereto.

In accordance with some embodiments, the second substrate 200 is disposed below the first substrate 100, and the second substrate 200 and the plurality of electronic components 400 are located on opposite surfaces of the first substrate 100. The second substrate 200 can serve as a circuit substrate. In accordance with some embodiments, the second substrate 200 may include a printed circuit board (PCB), a redistribution layer (RDL), or a combination thereof, but it is not limited thereto. In accordance with some other embodiments, the second substrate 200 may include a chip on film (COF), but it is not limited thereto.

Specifically, in accordance with some embodiments, the second substrate 200 may include a base and multiple insulating layers and interconnect layers (e.g., patterned conductive layers) disposed on the base. As shown in FIG. 2, in accordance with some embodiments, the electronic device 10 may further include an insulating layer 202, a first conductive material 220 and a second conductive pad 210. The insulating layer 202, the first conductive material 220 and the second conductive pad 210 may also be parts of the insulating layer and interconnect layer of the second substrate 200. The insulating layer 202, the first conductive material 220 and the second conductive pad 210 may be disposed between the second substrate 200 and the first substrate 100. In accordance with some other embodiments, the second substrate 200 may be an interposer.

The base of the second substrate 100 may include a rigid substrate, a flexible substrate, or a combination thereof. In accordance with some embodiments, the material of the base of the second substrate 100 may include glass, quartz, sapphire, polyimide (PI), polycarbonate (PC), polyethylene terephthalate (PET), polypropylene (PP), polydimethylsiloxane (PDMS), another suitable base material or a combination thereof, but it is not limited thereto.

In accordance with some embodiments, the insulating layer 202 may include a polymer insulating material, for example, may include Ajinomoto Build-up Film (ABF), polybenzoxazole (PBO), polyimide (PI), photosensitive polyimide (PSPI), benzocyclobutene (BCB), Preg, photoimageable dielectric (PID), resin coated cooper foil (RCC), flame-resistant fiberglass (FR4), fiberglass resin composite material, another suitable insulating material or a combination thereof, but it is not limited thereto.

In accordance with some embodiments, the electronic device 10 may further include an intermediate layer 102, and the intermediate layer 102 may be disposed between the first substrate 100 and the second substrate 200. In detail, a part of the intermediate layer 102 may be disposed between the insulating layer 202 and the first substrate 100, and a part of the intermediate layer 102 may be disposed between the first conductive material 220 and the first substrate 100. In accordance with some embodiments, the intermediate layer 102 may be an adhesive layer that can combine the first substrate 100 and the second substrate 200. For example, the intermediate layer 102 may be disposed on the second substrate 200 and then be combined with the first substrate 100, or the intermediate layer 102 may be disposed on the first substrate 100 and then combined with the second substrate 200. In accordance with some embodiments, the material of the intermediate layer 102 may include an inorganic material, an organic material, or a combination thereof, but it is not limited thereto. In accordance with some embodiments, the inorganic material may include silicon nitride, silicon oxide, silicon oxynitride, aluminum oxide, another suitable material, or a combination thereof, but it is not limited thereto. In accordance with some embodiments, the organic material may include, for example, perfluoroalkoxy alkane (PFA), polytetrafluoroethylene (PTFE), perfluorinated ethylene propylene (FEP), polyethylene, another suitable material or a combination thereof, but it is not limited thereto. In addition, in accordance with some embodiments, the intermediate layer 102 may include an adhesive material, such as optical clear adhesive (OCA), optical clear resin (OCR), pressure sensitive adhesive (PSA), acrylic glue, acrylic resin, another suitable material, or a combination thereof, but it is not limited thereto. Furthermore, the intermediate layer 102 may have a single-layer or multi-layer structure.

In addition, the electronic device 10 includes at least one electrical connection structure 10E. The electrical connection structure 10E may be disposed between the electronic components 400, for example, between two adjacent pixels PX1 and PX2, but it is not limited thereto. In other words, in accordance with some embodiments, the electrical connection structure 10E may be disposed in the active area and/or peripheral area of the electronic device 10. The electrical connection structure 10E can be applied to any suitable electronic device to provide electrical connection functions. The detailed structure of the electrical connection structure 10E will be described below.

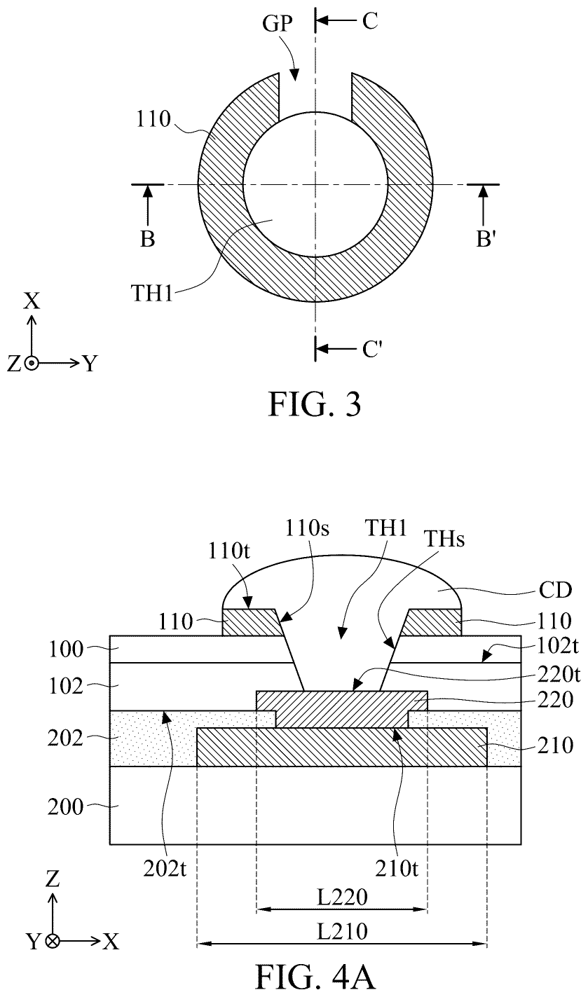

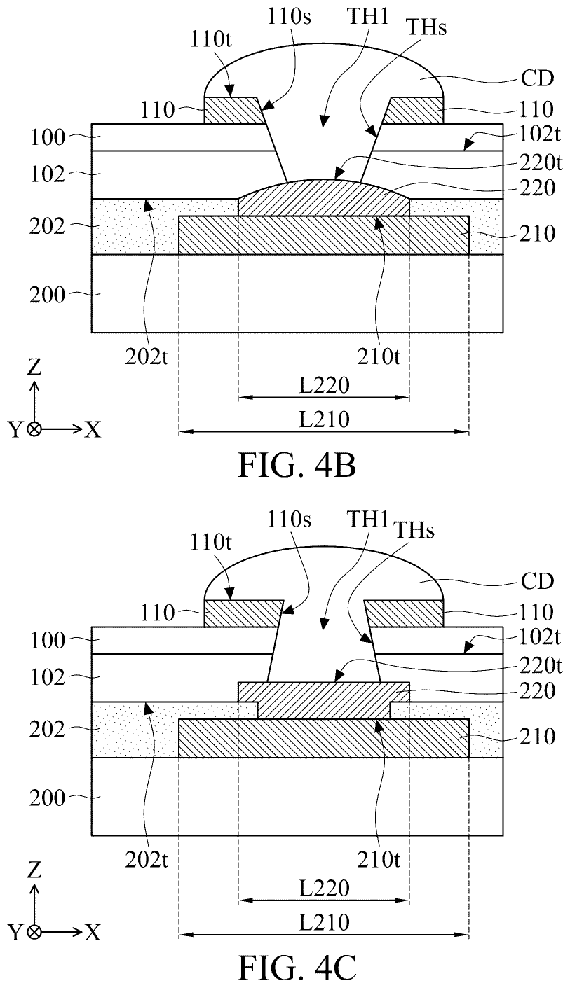

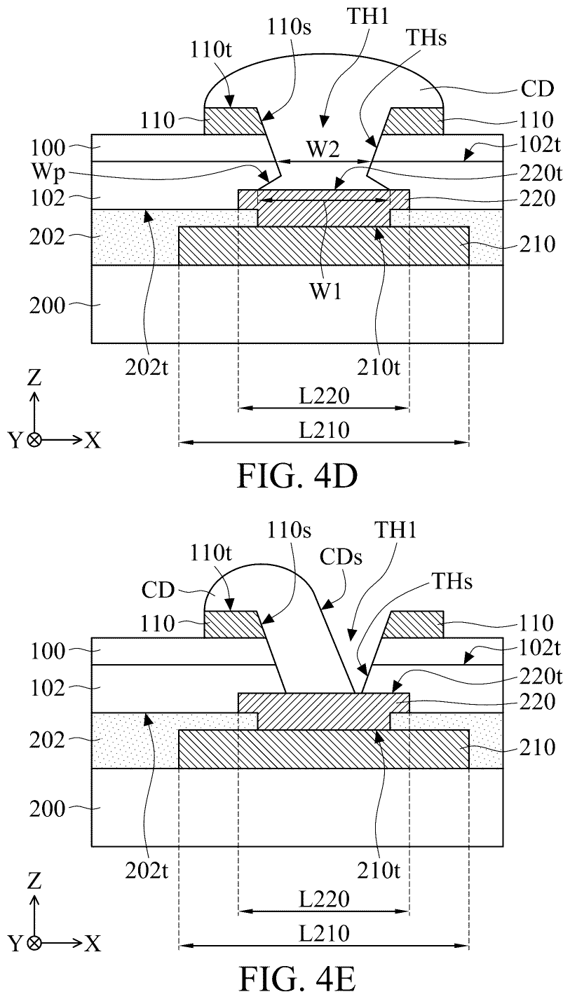

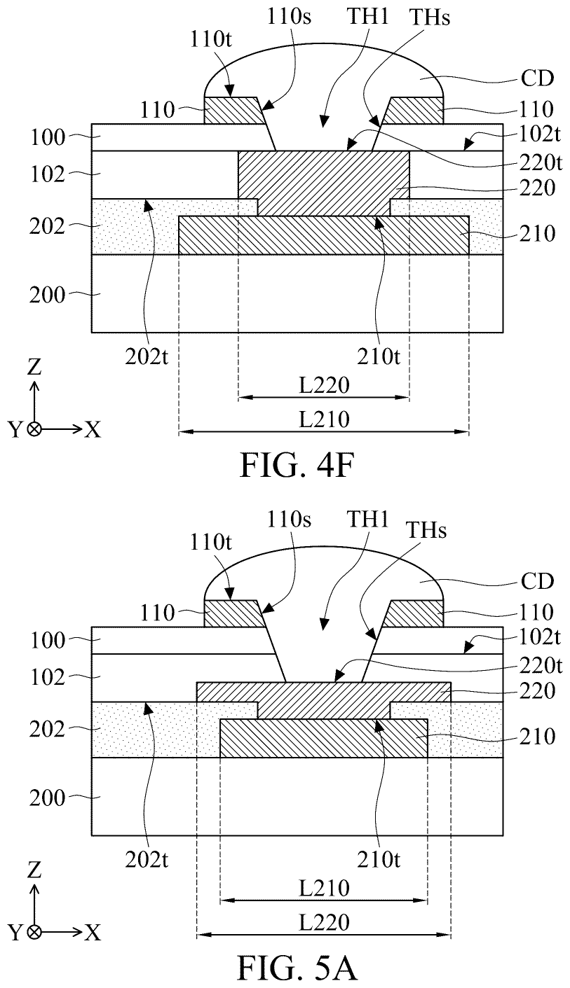

Please refer to FIG. 3 and FIG. 4A. FIG. 3 is a top-view diagram of some elements of an electrical connection structure 10E of an electronic device in accordance with some embodiments of the present disclosure. FIG. 4A is a cross-sectional diagram of the electrical connection structure 10E of the electronic device in accordance with some embodiments of the present disclosure. Specifically, FIG. 4A is a cross-sectional diagram of the electrical connection structure 10E taken along the section line B-B′ in FIG. 4A. Furthermore, FIG. 3 only illustrates the first conductive pad 110 and the through-hole TH1 of the electrical connection structure 10E to clearly explain the positional relationship between them.

In addition, it should be understood that the components or elements that are the same or similar to those mentioned above will be represented by the same or similar reference numerals below, and their materials and functions are the same or similar as those mentioned above, and thus will not be repeated in the following description.

First, as shown in FIG. 3 and FIG. 4A, the electrical connection structure 10E includes a first substrate 100, a first conductive pad 110, a second substrate 200, a second conductive pad 210, a first conductive material 220, a through-hole TH1 and a second conductive material CD.

The first conductive pad 110 is disposed on the first substrate 100. The first conductive pad 110 has a top surface 110t and a side surface 110s. In accordance with some embodiments, other stacked layers, such as a conductive layer, a semiconductor layer, an insulating layer, a protective layer, a planarization layer, an inorganic layer, an organic layer, etc., may be disposed between the first conductive pad 110 and the first substrate 100 or above the first substrate 100, but it is not limited thereto. In accordance with some embodiments, the first conductive pad 110 may be disposed on the top insulating layer of the circuit element layer (not illustrated) of the first substrate 100. For example, the first conductive pad 110 may be in contact with the top insulating layer of the circuit element layer, but it is not limited thereto. In accordance with some embodiments, other stacked layers, such as a conductive layer, a semiconductor layer, an insulating layer, a protective layer, a planarization layer, an inorganic layer, an organic layer, etc., may be disposed between the second conductive pad 210 and the second substrate 200 or above the second substrate 200, but it is not limited thereto.

As shown in FIG. 3, in accordance with some embodiments, the first conductive pad 110 has a gap GP, and the through-hole TH1 is partially surrounded by the first conductive pad 110. Specifically, the first conductive pad 110 is disposed around the through-hole TH1, but the first conductive pad 110 does not form a continuous and closed ring (for example, it may include a circular ring or a square ring, but it is not limited thereto). In accordance with some embodiments, the second conductive material CD may at least partially fill in the through-hole TH1, and make the first conductive pad 110 electrically connected to the first conductive material 220 through the through-hole TH1.

The first conductive pad 110 includes a conductive material. In accordance with some embodiments, the material of the first conductive pad 110 may include metal a conductive material, such as molybdenum (Mo), titanium (Ti), tantalum (Ta), niobium (Nb), hafnium (Hf), nickel (Ni), chromium (Cr), cobalt (Co), zirconium (Zr), tungsten (W), aluminum (Al), copper (Cu), tin (Sn), silver (Ag), gold (Au), alloys of the foregoing materials, another suitable conductive material or a combination thereof, but it is not limited thereto. In accordance with some embodiments, the material of the first conductive pad 110 may include a transparent conductive material. The transparent conductive material may include, for example, transparent conductive oxide (TCO), but it is not limited thereto.

The second conductive pad 210 is disposed on the second substrate 200, and the second conductive pad 210 has a top surface 210t. In accordance with some embodiments, the second conductive pad 210 may be a part of the interconnect layer of the second substrate 200, but it is not limited thereto. In accordance with some embodiments, the second conductive pad 210 may be further electrically connected to an electronic component (not illustrated, such as a driving component) disposed on the second substrate 200.

Furthermore, the material of the second conductive pad 210 may be the same as or similar to the material of the first conductive pad 110, and thus will not be repeated here.

The first conductive material 220 is disposed on the second conductive pad 210, and the first conductive material 220 has a top surface 220t. In accordance with some embodiments, the first conductive material 220 may be a part of the interconnect layer of the second substrate 200, but it is not limited thereto. In accordance with some embodiments, the first conductive material 220 may be electrically connected to an electronic component (not illustrated, such as a driving component) disposed on the second substrate 200 through the second conductive pad 210. In accordance with some embodiments, the first conductive material 220 may be in contact with the top surface 210t of the second conductive pad 210.

In accordance with some embodiments, the material of the first conductive material 220 includes a conductive material. In accordance with some embodiments, the material of the first conductive material 220 may include a metal conductive material, such as molybdenum (Mo), titanium (Ti), tantalum (Ta), niobium (Nb), hafnium (Hf), nickel (Ni), chromium (Cr), cobalt (Co), zirconium (Zr), tungsten (W), aluminum (Al), copper (Cu), tin (Sn), silver (Ag), gold (Au), alloys of the foregoing materials, another suitable conductive material or a combination thereof, but it is not limited thereto. In accordance with some embodiments, the material of the first conductive material 220 may include copper, tin, or a combination thereof. In accordance with some embodiments, the material of the first conductive material 220 may include a transparent conductive material. The transparent conductive material may include, for example, the aforementioned transparent conductive oxide (TCO), but it is not limited thereto. Furthermore, the material of the first conductive material 220 may be the same as or different from the materials of the first conductive pad 110 and the second conductive pad 210.

Furthermore, as described above, the electrical connection structure 10E may further include an insulating layer 202 and an intermediate layer 102. The insulating layer 202 may be disposed on the second substrate 200, and the intermediate layer 102 may be disposed between the insulating layer 202 and the first substrate 100.

The through-hole TH1 passes through the first conductive pad 110 and the first substrate 100. In accordance with some embodiments, the through-hole TH1 may pass through the first conductive pad 110, the first substrate 100, and the intermediate layer 102. In detail, in accordance with some embodiments, the intermediate layer 102 is at least partially in contact with the first conductive material 220, and the through-hole TH1 passes through the intermediate layer 102 and exposes a portion of the first conductive material 220, for example, exposes a portion of the top surface 220t of the first conductive material 220. The second conductive material CD may be at least partially disposed within the through-hole TH1 and at least partially contact the top surface 110t and the side surface 110s of the first conductive pad 110 and the first conductive material 220. The first conductive pad 110 may be electrically connected to the first conductive material 220 through the through-hole TH1, and then be electrically connected to the second conductive pad 210. The second conductive material CD may pass through the through-hole TH1, so that the first conductive pad 110 may be electrically to the first conductive material 220 and the second conductive pad 210. In accordance with some embodiments, the second conductive material CD may be in contact with the top surface 110t and the side surface 110s of the first conductive pad 110 and the top surface 220t of the first conductive material 220. In accordance with some embodiments, the second conductive material CD may be in contact with the top surface 110t and the side surface 110s of the first conductive pad 110, the first substrate 100, the intermediate layer 102, and the top surface 220t of the first conductive material 220.

Furthermore, the top surface 220t of the first conductive material 220 is higher than the top surface 202t of the insulating layer 202 but not higher than the top surface 102t of the intermediate layer 102. As shown in FIG. 4A, in accordance with some embodiments, the top surface 220t of the first conductive material 220 may be higher than the top surface 202t of the insulating layer 202 and lower than the top surface 102t of the intermediate layer 102. Since the top surface 220t of the first conductive material 220 is higher than the top surface 202t of the insulating layer 202, the first conductive material 220 may include a conductive bump, but it is not limited thereto.

Specifically, in accordance with some embodiments of the present disclosure, the relative height position relationship of the top surface 220t of the first conductive material 220, the top surface 202t of the insulating layer 202, and the top surface 102t of the intermediate layer 102 is, for example, compared in the normal direction of the normal direction of the second substrate 200 (for example, the Z direction in the figure). In addition, the comparison is made using the highest positions of the top surface 220t of the first conductive material 220, the top surface 202t of the insulating layer 202, and the top surface 102t of the intermediate layer 102. For example, if the aforementioned top surface is arc-shaped, curved or non-flat, the highest position of the top surface can be used for comparison.

It is noted that through the specific configuration of the first conductive material 220 described above, the first conductive pad 110 can be electrically connected to the second conductive pad 210 through the through-hole TH1 with a relatively small depth, so that the reliability of the electrical connection structure 10E can be improved and is conducive to miniaturization of electrical connection structures. In addition, the aforementioned configuration can reduce the volume of through-hole and reduce the demand for conductive material. This allows for a larger tolerance margin in the conductive material filling and/or through-hole processing, thereby improving process yield. However, in some embodiments, the top surface 220t of the first conductive material 220 may also be equal to or lower than the top surface 202t (not labeled) of the insulating layer 202, which is also beneficial to miniaturization of the electrical connection structure and can reduce the volume of through-hole and reduce the demand for conductive material, but the effect is less significant than the configuration in which the top surface 220t of the first conductive material 220 is higher than the top surface 202t of the insulating layer 202.

As shown in FIG. 4A, in accordance with some embodiments, a portion of the insulating layer 202 may be disposed between the first conductive material 220 and the second conductive pad 210. In other words, the insulating layer 202 may cover a portion of the second conductive pad 210, for example, cover the side surface (not labeled) and a portion of the top surface 210t of the second conductive pad 210. In addition, the maximum length L220 of the first conductive material 220 may be less than or equal to the maximum length L210 of the second conductive pad 210. In accordance with some embodiments, the maximum length L220 of the first conductive material 220 may be greater than the maximum length L210 of the second conductive pad 210. Furthermore, in accordance with some embodiments, in the cross-sectional diagram, a portion of the first conductive material 220 can serve as an upper portion of the first conductive material 220, which is located between the top surface 202t of the insulating layer 202 and the top surface 102t of the intermediate layer 102; and another portion of the first conductive material 220 can serve as a lower portion of the first conductive material 220, which is located between the top surface 202t of the insulating layer 202 and the top surface 210t of the second conductive pad 210. In accordance with some embodiments, as shown in FIG. 4A, the maximum length of the upper portion of the first conductive material 220 may be greater than the maximum length of the lower portion of the first conductive material 220. In accordance with some embodiments, the maximum height of the upper portion of the first conductive material 220 may be greater than the maximum height of the lower portion of the first conductive material 220. In accordance with some embodiments, the maximum height of the upper portion of the first conductive material 220 may be equal to the maximum height of the lower portion of the first conductive material 220. In accordance with some embodiments, the maximum height of the upper portion of the first conductive material 220 may be smaller than the maximum height of the lower portion.

In accordance with some embodiments of the present disclosure, the maximum length L220 of the first conductive material 220 refers to the maximum length of the first conductive material 220 in the direction perpendicular to the normal direction of the second substrate 200 (for example, the X direction in the figure); and the aforementioned maximum length L210 of the second conductive pad 210 refers to the maximum length of the second conductive pad 210 in the direction perpendicular to the normal direction of the second substrate 200 (for example, the X direction in the figure).

In addition, as shown in FIG. 4A, in accordance with some embodiments, the side surface THs of the through-hole TH1 (can also be regarded as the side surfaces of the first conductive pad 110, the first substrate 100 and the intermediate layer 102 in the through-holes TH1) may not be perpendicular to the top surface 220t of the first conductive material 220. In other words, the side surface THs of the through-hole TH1 may be inclined, for example, may be inclined outward from the bottom to the top (the top width of the through-hole TH1 is greater than the bottom width). In accordance with some other embodiments (not illustrated), the side surface THs of the through-hole TH1 may be substantially perpendicular to the top surface 220t of the first conductive material 220. In addition, in accordance with some embodiments, the side surface THs of the through-hole TH1 may include irregular or rough side walls, but it is not limited thereto.

Furthermore, the second conductive material CD may partially or entirely fill in the through-hole TH1. For example, in accordance with some embodiments (as shown in FIG. 4E), during the process of filling the second conductive material CD into the through-hole TH1, there may be a gap between the side surface of the second conductive material CD in the through-hole TH1 and the side surface THs of the through-hole TH1. In accordance with some embodiments (as shown in FIG. 4E), a portion of the side surface of the second conductive material CD may not contact the side surface THs of the through-hole TH1 and/or the side surface (not labeled) of the intermediate layer 102. During the process of disposing the second conductive material CD in the through-hole TH1, the air bubbles generated can be released through the gap between the side surface of the second conductive material CD and the side surface THs of the through-hole TH1. In this way, the risk of bubble formation in the second conductive material CD can be reduced, thereby reducing issues such as poor contact or electrical abnormalities between the second conductive material CD and the first conductive pad 110, the first conductive material 220 or the second conductive pad 210.

In accordance with some embodiments, one or more photolithography processes and/or etching processes may be used to remove parts of the first substrate 100 and the intermediate layer 102 to form the through-hole TH1. In accordance with some embodiments, the photolithography process may include photoresist coating (e.g., spin coating), soft baking, hard baking, mask alignment, exposure, post-exposure baking, photoresist development, cleaning and drying, etc., but it is not limited thereto. The etching process may include a dry etching process or a wet etching process, but it is not limited thereto.

Furthermore, the second conductive material CD may include a conductive material. In accordance with some embodiments, the material of the second conductive material CD may include silver paste, copper paste, solder paste, conductive solder, another suitable conductive material, or a combination thereof, but it is not limited thereto. In accordance with some embodiments, solder paste printing process, micro inkjet printing (MJP) process, chemical vapor deposition (CVD) process, physical vapor deposition (PVD) process, an electroplating process, an electroless plating process, another suitable method or a combination thereof may be used to dispose the second conductive material CD in the through-hole TH1. Furthermore, in accordance with some embodiments, the surface of the second conductive material CD may have an arc profile.

Next, please refer to FIG. 4B, which is a cross-sectional diagram of an electrical connection structure of an electronic device in accordance with some other embodiments of the present disclosure. Specifically, FIG. 4B is a cross-sectional diagram of the electrical connection structure taken along the section line B-B′ in FIG. 3.

It should be understood that the components or elements that are the same or similar to those mentioned above will be represented by the same or similar reference numerals below, and their materials and functions are the same or similar as those mentioned above, and thus will not be repeated in the following description.

The electrical connection structure shown in FIG. 4B is substantially similar to that in FIG. 4A. Compared with the embodiment shown in FIG. 4A, in this embodiment, the top surface 220t of the first conductive material 220 has an arc profile. Similarly, the top surface 220t of the first conductive material 220 is higher than the top surface 202t of the insulating layer 202 and lower than the top surface 102t of the intermediate layer 102. Furthermore, the insulating layer 202 may cover a portion of the second conductive pad 210, for example, cover a side surface (not labeled) of the second conductive pad 210. In addition, the maximum length L220 of the first conductive material 220 may be smaller than the maximum length L210 of the second conductive pad 210. Furthermore, in the cross-sectional diagram, the maximum length of the upper portion of the first conductive material 220 may be substantially equal to the maximum length of the lower portion.

Next, please refer to FIG. 4C, which is a cross-sectional diagram of an electrical connection structure of an electronic device in accordance with some other embodiments of the present disclosure. Specifically, FIG. 4C is a cross-sectional diagram of the electrical connection structure taken along the section line B-B′ in FIG. 3.

The electrical connection structure shown in FIG. 4C is substantially similar to that in FIG. 4A. Compared with the embodiment shown in FIG. 4A, in this embodiment, the side surface THs of the through-hole TH1 is not perpendicular to the top surface 220t of the first conductive material 220, and the side surface THs of the through-hole TH1 is inclined. The side surface THs is inclined inward from bottom to top (that is, the top width of the through-hole TH1 is smaller than the bottom width). Similarly, the top surface 220t of the first conductive material 220 is higher than the top surface 202t of the insulating layer 202 and lower than the top surface 102t of the intermediate layer 102. Furthermore, a portion of the insulating layer 202 may be disposed between the first conductive material 220 and the second conductive pad 210. In other words, the insulating layer 202 may cover a portion of the second conductive pad 210, for example, cover the side surface (not labeled) and a portion of the top surface 210t of the second conductive pad 210. In addition, the maximum length L220 of the first conductive material 220 may be smaller than the maximum length L210 of the second conductive pad 210. Furthermore, in the cross-sectional diagram, the maximum length of the upper portion of the first conductive material 220 may be smaller than the maximum length of the lower portion.

Next, please refer to FIG. 4D, which is a cross-sectional diagram of an electrical connection structure of an electronic device in accordance with some other embodiments of the present disclosure. Specifically, FIG. 4D is a cross-sectional diagram of the electrical connection structure taken along the section line B-B′ in FIG. 3.

The electrical connection structure shown in FIG. 4D is substantially similar to that in FIG. 4A. Compared with the embodiment shown in FIG. 4A, in this embodiment, the second conductive material CD has an extension portion Wp, and the extension portion Wp is in contact with the first conductive material 220. The extension portion Wp may be in contact, for example, with the top surface 220t of the first conductive material 220. Furthermore, the extension portion Wp has a first width W1, and the second conductive material CD has a second width W2 at the interface between the first substrate 100 and the intermediate layer 102, and the first width W1 is greater than the second width W2. In accordance with some embodiments, the first width W1 may be less than the maximum length L220 of the first conductive material 220.

In accordance with some embodiments of the present disclosure, the first width W1 of the aforementioned extension portion Wp refers to the maximum width of the extension portion Wp of the second conductive material 220 in the direction perpendicular to the normal direction of the second substrate 200 (for example, the X direction in the figure); and the second width W2 of the second conductive material 220 refers to the maximum width of the second conductive material CD at the interface between the first substrate 100 and the intermediate layer 102 in the direction perpendicular to the normal direction of the second substrate 200 (for example, the X direction in the figure).

It should be noted that the arrangement of the extension portion Wp can increase the contact area between the second conductive material CD and the first conductive material 220, and can laterally increase the conductive material filling volume of the through-hole TH1, thereby reducing the impedance and improving the reliability of electrical connection. In addition, as shown in FIG. 4D, in this embodiment, the top surface 220t of the first conductive material 220 is higher than the top surface 202t of the insulating layer 202 and lower than the top surface 102t of the intermediate layer 102. Furthermore, a portion of the insulating layer 202 may be disposed between the first conductive material 220 and the second conductive pad 210. In other words, the insulating layer 202 may cover a portion of the second conductive pad 210, for example, cover the side surface (not labeled) and a portion of the top surface 210t of the second conductive pad 210. In addition, the maximum length L220 of the first conductive material 220 may be smaller than the maximum length L210 of the second conductive pad 210. Furthermore, in the cross-sectional diagram, the maximum length of the upper portion of the first conductive material 220 may be greater than the maximum length of the lower portion. In accordance with some embodiments, in the cross-sectional diagram, the maximum length L220 of the first conductive material 220 may be greater than or equal to the maximum length L210 of the second conductive pad 210. In accordance with some embodiments, the maximum height of the upper portion of the first conductive material 220 may be greater than the maximum height of the lower portion. In accordance with some embodiments, the maximum height of the upper portion of the first conductive material 220 may be equal to the maximum height of the lower portion. In accordance with some embodiments, the maximum height of the upper portion of the first conductive material 220 may be smaller than the maximum height of the lower portion.

Next, please refer to FIG. 4E, which is a cross-sectional diagram of an electrical connection structure of an electronic device in accordance with some other embodiments of the present disclosure. Specifically, FIG. 4E is a cross-sectional diagram of the electrical connection structure taken along the section line B-B′ in FIG. 3.

The electrical connection structure shown in FIG. 4E is substantially similar to that in FIG. 4A. Compared with the embodiment shown in FIG. 4A, in this embodiment, the second conductive material CD partially fills in the through-hole TH1. Specifically, there is a gap between the side surface CDs of the second conductive material CD in the through-hole TH1 and the side surface THs of the through-hole TH1. A portion of the side surface CDs of the second conductive material CD may not contact the side surface THs of the through-hole TH1 and/or the side surface (not labeled) of the intermediate layer 102. During the process of disposing the second conductive material CD in the through-hole TH1, the air bubbles generated can be released through the gap between the side surface of the second conductive material CD and the side surface THs of the through-hole TH1. In this way, the risk of bubble formation in the second conductive material CD can be reduced, thereby reducing issues such as poor contact or electrical abnormalities between the second conductive material CD and the first conductive pad 110, the first conductive material 220 or the second conductive pad 210.

In addition, as shown in FIG. 4E, in this embodiment, the top surface 220t of the first conductive material 220 is higher than the top surface 202t of the insulating layer 202 and lower than the top surface 102t of the intermediate layer 102. Furthermore, a portion of the insulating layer 202 may be disposed between the first conductive material 220 and the second conductive pad 210. In other words, the insulating layer 202 may cover a portion of the second conductive pad 210, for example, cover the side surface (not labeled) and a portion of the top surface 210t of the second conductive pad 210. In addition, the maximum length L220 of the first conductive material 220 may be smaller than the maximum length L210 of the second conductive pad 210. Furthermore, in the cross-sectional diagram, the maximum length of the upper portion of the first conductive material 220 may be greater than the maximum length of the lower portion.

Next, please refer to FIG. 4F, which is a cross-sectional diagram of an electrical connection structure of an electronic device in accordance with some other embodiments of the present disclosure. Specifically, FIG. 4F is a cross-sectional diagram of the electrical connection structure taken along the section line B-B′ in FIG. 3.

The electrical connection structure shown in FIG. 4F is substantially similar to that in FIG. 4A. Compared with the embodiment shown in FIG. 4A, in this embodiment, the top surface 220t of the first conductive material 220 is higher than the top surface 202t of the insulating layer 202 and is substantially aligned with the top surface 102t of the intermediate layer 102. In other words, the top surface 220t of the first conductive material 220 and the top surface 102t of the intermediate layer 102 may be substantially coplanar. In this embodiment, the intermediate layer 102 does not cover the top surface 220t of the first conductive material 220.

In addition, as shown in FIG. 4F, in this embodiment, a portion of the insulating layer 202 may be disposed between the first conductive material 220 and the second conductive pad 210. In other words, the insulating layer 202 may cover a portion of the second conductive pad 210, for example, cover the side surface (not labeled) and a portion of the top surface 210t of the second conductive pad 210. In addition, the maximum length L220 of the first conductive material 220 may be smaller than the maximum length L210 of the second conductive pad 210. Furthermore, in the cross-sectional diagram, the maximum length of the upper portion of the first conductive material 220 may be greater than the maximum length of the lower portion. In this embodiment, in the cross-sectional diagram, the maximum height of the upper portion of the first conductive material 220 may be greater than the maximum height of the lower portion.

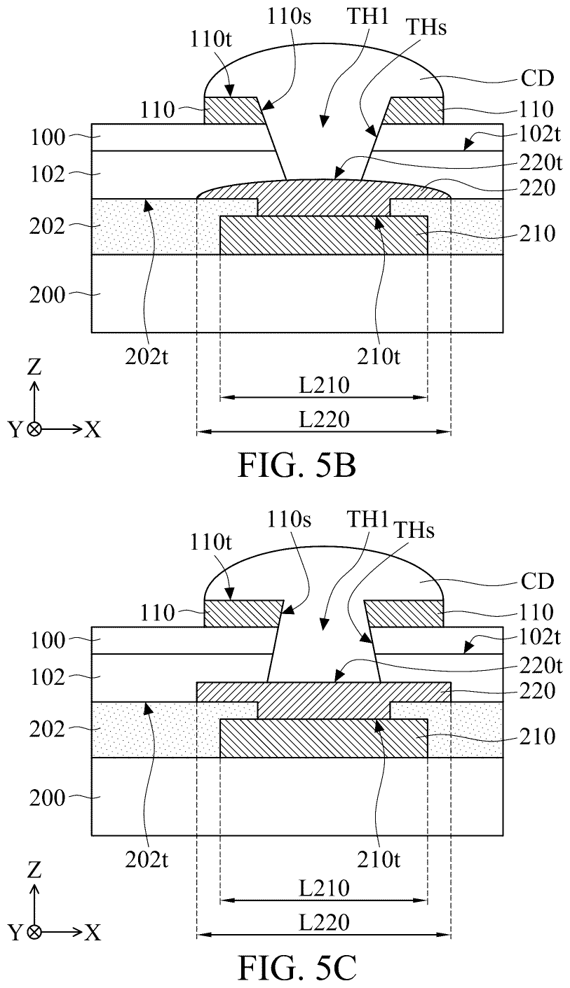

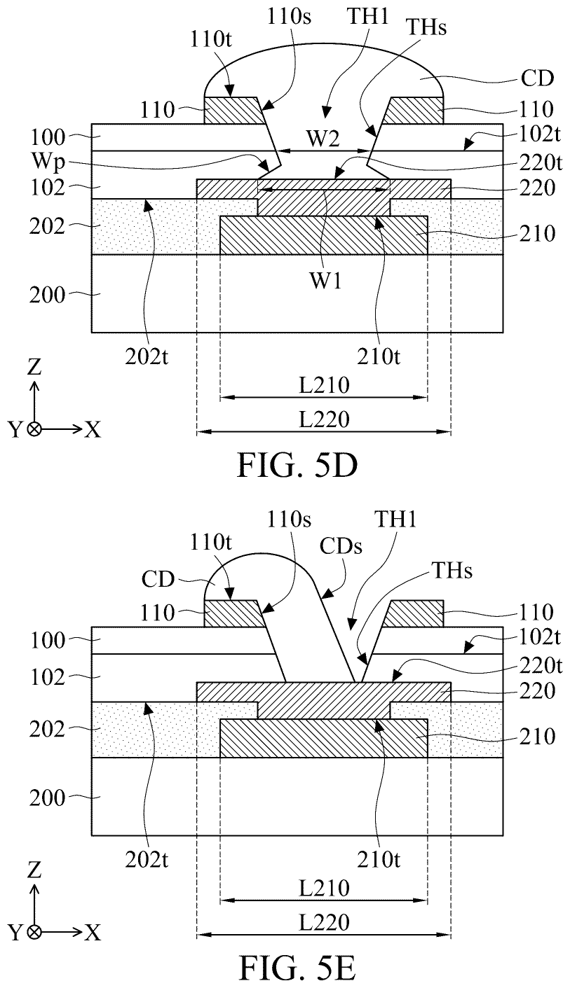

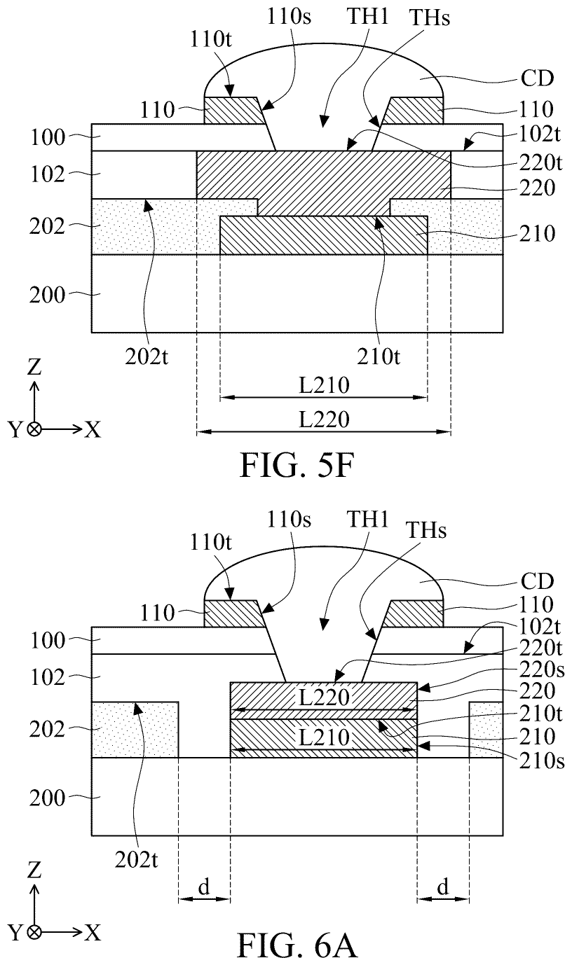

Next, please refer to FIGS. 5A to 5F, which are cross-sectional diagrams of an electrical connection structure of an electronic device in accordance with some embodiments of the present disclosure. Specifically, FIGS. 5A to 5F are cross-sectional diagrams of the electrical connection structure taken along the section line B-B′ in FIG. 3.

The electrical connection structures shown in FIGS. 5A to 5F are substantially similar to that of FIGS. 4A to 4F, respectively. Compared with the embodiments shown in FIGS. 4A to 4F, in these embodiments, the maximum length L210 of the second conductive pad 210 is smaller than the maximum length L220 of the first conductive material 220. Furthermore, in the cross-sectional diagram, the maximum length of the upper portion of the first conductive material 220 may be greater than the maximum length of the lower portion. Moreover, the maximum length of the upper portion of the first conductive material 220 may also be greater than the maximum length L210 of the second conductive pad 210.

In particular, in accordance with some embodiments, when the aforementioned configuration in which the maximum length L210 of the second conductive pad 210 is smaller than the maximum length L220 of the first conductive material 220 is adopted (that is, the first conductive material 220 has a relatively large size (length, area, volume, etc.)), the difficulty of arranging or routing other electronic components on the second substrate 200 can be reduced and the process yield can be improved. Furthermore, the first conductive material 220 with a relatively large size can also reduce the impedance of the first conductive material 220 (increase the conductive ability of the first conductive material 220), which is beneficial to miniaturization of the electrical connection structure. In addition, this allows for a larger tolerance margin in the conductive material filling and/or through-hole processing.

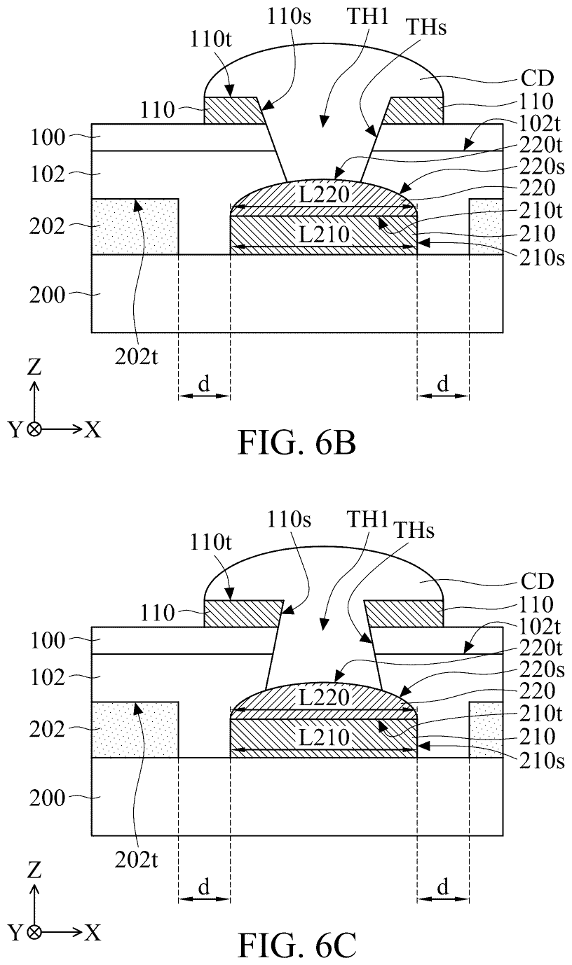

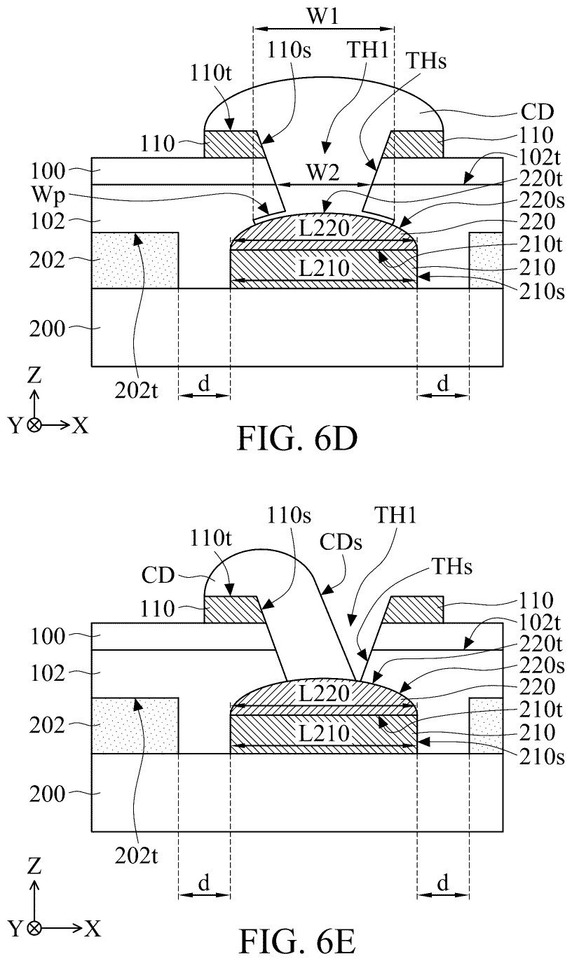

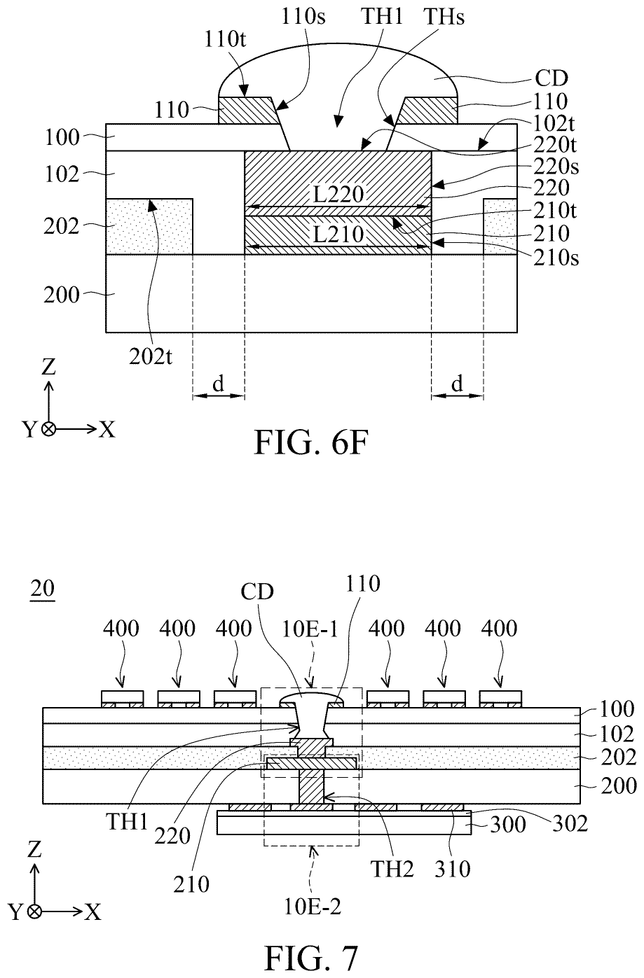

Next, please refer to FIGS. 6A to 6F, which are cross-sectional diagrams of an electrical connection structure of an electronic device in accordance with some embodiments of the present disclosure. Specifically, FIGS. 6A to 6F are schematic cross-sectional structural diagrams of the electrical connection structure taken along the section line B-B′ in FIG. 3.

The electrical connection structures shown in FIGS. 6A to 6F are substantially similar to that of FIGS. 4A to 4F, respectively. Compared with the embodiments shown in FIGS. 4A to 4F, in these embodiments, the insulating layer 202 does not cover the second conductive pad 210, and the insulating layer 202 and the second conductive pad 210 are separated by a first distance d. The first distance d may be greater than or equal to 0. For example, the second conductive pad 210 may first be formed on the second substrate 200 and serve as a seed layer, and then the first conductive material 220 may be formed on the first conductive material 220. In these embodiments, the maximum length L210 of the second conductive pad 210 is substantially equal to the maximum length L220 of the first conductive material 220. The side surface 210s of the second conductive pad 210 may be substantially aligned with the side surface 220s of the first conductive material 220. In other words, the side surface 210s of the second conductive pad 210 and the side surface 220s of the first conductive material 220 may be substantially coplanar.

In particular, in accordance with some embodiments, when the aforementioned configuration in which the insulating layer 202 does not cover the second conductive pad 210 is adopted, the first conductive material 220 can be entirely disposed above the second conductive pad 210, for example, entirely covering the top surface 210t of the second conductive pad 210. This allows the first conductive material 220 and the second conductive pad 210 to have a relatively large contact area, thereby improving the conductive performance of the electrical connection structure. In accordance with some embodiments, as shown in FIGS. 6A to 6F, a portion of the intermediate layer 102 may be disposed between the insulating layer 202 and the second conductive pad 210. In accordance with some embodiments, other film layers may be additionally disposed between the insulating layer 202 and the second conductive pad 210. In accordance with some embodiments, a portion of the intermediate layer 102 and other film layers may be disposed between the insulating layer 202 and the second conductive pad 210. In accordance with some embodiments, the first distance d may be equal to 0 on at least one side, and then the at least one side wall of the insulating layer 202 is in direct contact with the at least one side wall of the second conductive pad 210.

Next, please refer to FIG. 7, which is a cross-sectional diagram of an electronic device 20 in accordance with some other embodiments of the present disclosure. It should be understood that, for clarity of explanation, some components of the electronic device 20 may be omitted in the drawings, and only some components are schematically illustrated. In accordance with some embodiments, additional features may be added to the electronic device 20 described below. In accordance with some other embodiments, some features of the electronic device 20 described below may be replaced or omitted.

As shown in FIG. 7, in accordance with some embodiments, the electronic device 20 includes an electrical connection structure 10E-1 and an electrical connection structure 10E-2. Specifically, the electrical connection structure 10E-1 is substantially the same as the electrical connection structure 10E in the embodiment shown in FIG. 2. Compared with the electronic device 10 shown in FIG. 2, the electronic device 20 further includes the electrical connection structure 10E-2 and the electrical connection structure 10E-2 can be electrically connected to the electrical connection structure 10E-1. In accordance with some embodiments, in the normal direction of the first substrate 100 (e.g., the Z direction in the figure), the electrical connection structure 10E-2 and the electrical connection structure 10E-1 at least partially overlap.

In detail, in accordance with some embodiments, the electrical connection structure 10E-2 may include a third substrate 300, a third conductive pad 310 and a through-hole TH2. The third conductive pad 310 may be disposed between the third substrate 300 and the second conductive pad 210, the through-hole TH2 may pass through the second substrate 200, and the third conductive pad 310 may be electrically connected to the second conductive pad 210 through the through-hole TH2. Specifically, a conductive material is also provided in the through-hole TH2, and the third conductive pad 310 may be electrically connected to the second conductive pad 210 through the conductive material provided in the through-hole TH2.

The materials of the third substrate 300 and the third conductive pad 310 may be the same as or similar to the materials of the aforementioned second substrate 200 and the second conductive pad 210, and thus will not be repeated here.

Furthermore, the electronic device 20 may include an electronic component 400 and a driving component 302. The electronic component 400 may be disposed on the first substrate 100, and the driving component 302 may be disposed on the third substrate 300. In addition, the driving element 302 may be electrically connected to the electronic component 400 through the electrical connection structure 10E-1 and the electrical connection structure 10E-2. As mentioned above, in accordance with some embodiments, the electronic component 400 may include a light-emitting diode, but it is not limited thereto. Furthermore, in accordance with some embodiments, the driving element 302 may include an integrated circuit chip (IC), a microchip, or another suitable electronic driving element that can provide electronic signals or logic signals, but it is not limited thereto. In accordance with some embodiments, the driving element 302 may be disposed on the third substrate 300 in the form of a chip on film (COF) package or a chip on glass (COG) package, but it is not limited thereto.

The second conductive material CD of the electronic device 20 may be electrically connected to the second conductive pad 210 and the third conductive pad 310 through the through-hole TH1 and the through-hole TH2, and then be electrically connected to the driving element 302 on the third substrate 300. Through the above configuration, the driving signal of the driving element 302 can be provided to the first conductive pad 110 and the electronic components 400 through the conductive path formed by the second conductive material CD, the second conductive pad 210 and the third conductive pad 310. When the electronic device 20 is applied in the field of display devices, the driving signal of the driving component 302 can be transmitted from one side of the first substrate 100 to the electronic components 400 on the opposite side through the electrical connection structure 10E-1 and the electrical connection structure 10E-2. Therefore, the driving element 302 can be disposed on the back side of the first substrate 100, thereby reducing the peripheral usage of the electronic device 20, thereby achieving the technical requirements of bezel-free, narrow-bezel, or seamless tiling with good display quality. In accordance with some embodiments, in the normal direction of the first substrate 100 (for example, the Z direction in the figure), the electrical connection structure 10E-2 and the electrical connection structure 10E-1 may not overlap. The electrical connection structure 10E-2 may be electrically connected to the electrical connection structure 10E-1 through wires or other conductors. In accordance with some embodiments, at least one of the electrical connection structure 10E-1 and the electrical connection structure 10E-2 includes the first conductive material 220.

In addition, in accordance with some other embodiments, the aforementioned electrical connection structure can also be applied to the tiled device to provide electrical connections between different parts of the tiled device. Moreover, the electrical connection structure can be used to provide conduction between any suitable number of substrates, and the number of electrical connection structures and substrates is not limited to those shown in the drawings of the present disclosure.

To summarize the above, in accordance with the embodiments of the present disclosure, the electrical connection structure provided is conducive to miniaturization of the electrical connection structure, which can reduce the volume of the through-holes, decrease the required amount of conductive material, or reduce the depth of the through-holes. This allows for a larger tolerance margin in the conductive material filling and/or through-hole processing, thereby improving the reliability of the electrical connection structure and the process yield. In addition, in accordance with the embodiments of the present disclosure, the design of the electrical connection structure allows electronic components (e.g., driving elements) to be placed on the backside of the substrate, reducing the peripheral usage of the electronic device and thereby meeting technological requirements such as bezel-free, narrow-bezel, or seamless tiling designs.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
at least one electrical connection structure, wherein the at least one electrical connection structure comprises:
a first substrate;
a first conductive pad disposed on the first substrate, wherein the first conductive pad has a top surface and a side surface;
a second substrate;
a second conductive pad disposed on the second substrate;
a first conductive material disposed on the second conductive pad;
a through-hole passing through the first conductive pad and the first substrate; and
a second conductive material partially disposed within the through-hole and is at least partially in contact with the top surface and the side surface of the first conductive pad and the first conductive material.

2. The electronic device as claimed in claim 1, further comprising:
an insulating layer disposed on the second substrate; and
an intermediate layer disposed between the insulating layer and the first substrate.

3. The electronic device as claimed in claim 2, wherein a top surface of the first conductive material is higher than a top surface of the insulating layer and not higher than a top surface of the intermediate layer.

4. The electronic device as claimed in claim 3, wherein the top surface of the first conductive material has an arc profile.

5. The electronic device as claimed in claim 2, wherein the intermediate layer is at least partially in contact with the first conductive material, and the through-hole passes through the intermediate layer and exposes a portion of the first conductive material.

6. The electronic device as claimed in claim 2, wherein a portion of the insulating layer is disposed between the first conductive material and the second conductive pad.

7. The electronic device as claimed in claim 1, further comprising:
an insulating layer disposed on the second substrate, wherein the insulating layer and the second conductive pad are separated by a first distance, and the first distance is greater than or equal to 0.

8. The electronic device as claimed in claim 1, wherein a maximum length of the second conductive pad is less than or equal to a maximum length of the first conductive material.

9. The electronic device as claimed in claim 1, wherein a maximum length of the first conductive material is less than or equal to a maximum length of the second conductive pad.

10. The electronic device as claimed in claim 2, wherein the second conductive material has an extension portion, the extension portion is in contact with the first conductive material, and the extension portion has a first width, the second conductive material has a second width at an interface between the first substrate and the intermediate layer, and the first width is greater than the second width.

11. The electronic device as claimed in claim 10, wherein the first width is smaller than a maximum length of the first conductive material.

12. The electronic device as claimed in claim 1, wherein a maximum length of an upper portion of the first conductive material is greater than a maximum length of a lower portion of the first conductive material.

13. The electronic device as claimed in claim 1, wherein a maximum height of an upper portion of the first conductive material is greater than a maximum height of a lower portion of the first conductive material.

14. The electronic device as claimed in claim 1, wherein a maximum height of an upper portion of the first conductive material is equal to a maximum height of a lower portion of the first conductive material.

15. The electronic device as claimed in claim 1, wherein a maximum height of an upper portion of the first conductive material is smaller than a maximum height of a lower portion of the first conductive material.

16. The electronic device as claimed in claim 1, further comprising another electrical connection structure, wherein the another electrical connection structure is electrically connected to the at least one electrical connection structure.

17. The electronic device as claimed in claim 16, wherein the another electrical connection structure at least partially overlaps the at least one electrical connection structure.

18. The electronic device as claimed in claim 16, wherein the another electrical connection structure comprises:
a third substrate; and
a third conductive pad disposed between the third substrate and the second conductive pad.

19. The electronic device as claimed in claim 18, wherein the another electrical connection structure further comprises:
another through hole passing through the second substrate, wherein the third conductive pad is electrically connected to the second conductive pad through the another through hole.

20. The electronic device as claimed in claim 18, further comprising:
an electronic component disposed on the first substrate; and
a driving element disposed on the third substrate,
wherein the driving element is electrically connected to the electronic component through the at least one electrical connection structure and the another electrical connection structure.
